(19) United States
(12) Patent Application Publication
(10) Pub. No.: US 2023/0108829 A1
(43) Pub. Date: Apr. 6, 2023

(54) PRESSURE-SENSITIVE ADHESIVE COMPOSITION TO BE USED IN PRESSURE-SENSITIVE ADHESIVE TAPE FOR SEMICONDUCTOR PROCESSING AND PRESSURE-SENSITIVE ADHESIVE TAPE USING THE PRESSURE-SENSITIVE ADHESIVE COMPOSITION

(71) Applicant: NITTO DENKO CORPORATION, Osaka (JP)

(72) Inventors: Mariko TESHIBA, Ibaraki-shi (JP); Hiroki KONO, Ibaraki-shi (JP)

(21) Appl. No.: 17/956,718

(22) Filed: Sep. 29, 2022

(30) Foreign Application Priority Data
Oct. 1, 2021 (JP) 2021-162678

(51) Int. Cl. C09J 7/38; C09J 7/25

(52) U.S. Cl. CPC C09J 7/385; C09J 7/255; B32B 27/08

(57) ABSTRACT

Provided is a pressure-sensitive adhesive composition to be used in a pressure-sensitive adhesive tape for semiconductor processing, which has an excellent unevenness-embedding property and an excellent pressure-sensitive adhesive property, and can prevent adhesive residue on an adherend at the time of its peeling. The pressure-sensitive adhesive composition to be used in a pressure-sensitive adhesive tape for semiconductor processing includes a base polymer and a photopolymerization initiator, wherein the base polymer is a polymer obtained by polymerizing a monomer composition containing a polymer having a hydroxy group and a monomer represented by the following formula:

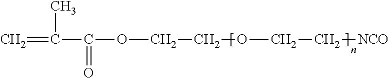

where “n” represents an integer of 1 or more.

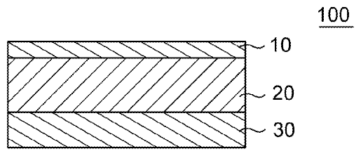

### BACKGROUND OF THE INVENTION

This application claims priority under 35 U.S.C Section 119 to Japanese Patent Application No.2021-162678 filed on Oct. 1, 2021 which is herein incorporated by reference.

### 1. Field of the Invention

The present disclosure relates to a pressure-sensitive adhesive composition to be used in a pressure-sensitive adhesive tape for semiconductor processing and a pressure-sensitive adhesive tape using the pressure-sensitive adhesive composition.

### 2. Description of the Related Art

A semiconductor wafer is used for various usages, such as a personal computer, a smartphone, and an automobile. In the processing step of the semiconductor wafer, a pressure-sensitive adhesive tape is used for protecting a surface thereof at the time of processing. In recent years, the miniaturization and high functionalization of large-scale integration (LSI) have been proceeding, and a surface structure of the wafer has become complicated. A specific example thereof is the complication of the three-dimensional structure of the wafer surface by a solder bump or the like. Accordingly, the pressure-sensitive adhesive tape to be used in the semiconductor processing step is required to have such a property as to embed the unevenness of the wafer surface and a strong pressure-sensitive adhesive property.

In recent years, along with the downsizing and thinning of products, the thinning of the semiconductor wafer has been advanced. In the wafer processed into a thin shape, when the pressure-sensitive adhesive strength of the pressure-sensitive adhesive tape is too high, the wafer may be broken at the time of the peeling of the pressure-sensitive adhesive tape. Accordingly, in order to prevent adhesive residue on an adherend and the breakage of the wafer at the time of the peeling of the tape, a pressure-sensitive adhesive tape using a UV-curable pressure-sensitive adhesive has been proposed (for example, Japanese Patent Application Laid-open No. 2020-017758 and Japanese Patent Application Laid-open No. 2013-213075). However, even when the UV-curable pressure-sensitive adhesive is used, the problems of adhesive residue on the adherend and the breakage of the wafer due to an insufficient reduction in pressure-sensitive adhesive strength may occur.

### SUMMARY OF THE INVENTION

The present disclosure has been made to solve the above-mentioned problem of the related art, and provides a pressure-sensitive adhesive composition to be used in a pressure-sensitive adhesive tape for semiconductor processing, which has an excellent unevenness-embedding property and an excellent pressure-sensitive adhesive property, and can prevent adhesive residue on an adherend at the time of its peeling.

According to at least one embodiment of the present disclosure, provided is a pressure-sensitive adhesive composition to be used in a pressure-sensitive adhesive tape for semiconductor processing, including a base polymer and a photopolymerization initiator, wherein the base polymer is obtained by polymerizing a monomer composition containing a polymer having a hydroxy group and a monomer represented by the following formula:

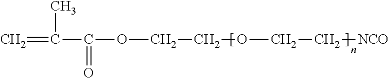

where “n” represents an integer of 1 or more.

In at least one embodiment of the present disclosure, an addition amount of the monomer represented by the formula with respect to the hydroxy group of the polymer having a hydroxy group is from 50 mol % to 95 mol %.

In at least one embodiment of the present disclosure, the monomer represented by the formula is 2-(2-methacryloyloxyethyloxy) ethyl isocyanate.

In at least one embodiment of the present disclosure, a monomer composition to be used in polymerization of the polymer having a hydroxy group contains a hydroxy group-containing monomer at a ratio of 10 mol % to 40 mol %.

According to another aspect of the present disclosure, provided is a pressure-sensitive adhesive tape for semiconductor processing. The pressure-sensitive adhesive tape for semiconductor processing includes a base material and a pressure-sensitive adhesive layer formed from the pressure-sensitive adhesive composition.

In at least one embodiment of the present disclosure, the pressure-sensitive adhesive tape for semiconductor processing is configured to be used in a backgrinding step.

In at least one embodiment of the present disclosure, the pressure-sensitive adhesive layer has a shear storage modulus of elasticity at 25° C. of 0.2 MPa or more when being free from being irradiated with UV light.

In at least one embodiment of the present disclosure, the pressure-sensitive adhesive tape for semiconductor processing is configured to be bonded to an adherend having unevenness.

In at least one embodiment of the present disclosure, the pressure-sensitive adhesive layer has a tensile storage modulus of elasticity at 25° C. of 200 MPa or less after UV irradiation.

In at least one embodiment of the present disclosure, the pressure-sensitive adhesive layer has a pressure-sensitive adhesive strength to silicon of 0.15 N/20 mm or less after UV irradiation.

### BRIEF DESCRIPTION OF THE DRAWINGS

The FIGURE is a schematic sectional view of a pressure-sensitive adhesive tape according to at least one embodiment of the present disclosure.

### DESCRIPTION OF THE EMBODIMENTS

Pressure-Sensitive Adhesive Composition to be Used in Pressure-Sensitive Adhesive Tape for Semiconductor Processing

A pressure-sensitive adhesive composition to be used in a pressure-sensitive adhesive tape for semiconductor wafer processing according to at least one embodiment of the present disclosure includes a base polymer and a photopolymerization initiator. The base polymer is a polymer obtained by polymerizing a monomer composition containing a polymer having a hydroxy group and a monomer represented by formula (1). The pressure-sensitive adhesive tape using the pressure-sensitive adhesive composition including the photopolymerization initiator is improved in peelability by applying UV light at the time of its peeling to cure its pressure-sensitive adhesive layer. Even when the pressure-sensitive adhesive composition including the photopolymerization initiator is used, in the case where the composition is used in the processing of a semiconductor wafer having unevenness on its surface, adhesive residue may occur. When the polymer obtained by polymerizing the monomer composition containing the monomer component represented by formula (1) is used as the base polymer of the pressure-sensitive adhesive composition, a pressure-sensitive adhesive composition is obtained, which can prevent adhesive residue on an adherend at the time of its peeling even in the case of being used in the processing of a semiconductor wafer having unevenness on its surface. Further, the pressure-sensitive adhesive composition including the base polymer can exhibit such an excellent property as to embed the unevenness of the surface of a semiconductor wafer and an excellent pressure-sensitive adhesive property. Accordingly, the pressure-sensitive adhesive composition according to at least one embodiment of the present disclosure may be suitably used in the processing of a semiconductor wafer having a complicated surface structure. In this specification, the monomer composition may be a composition containing only the monomer, or may be a composition containing the monomer and any appropriate other component, such as an oligomer or a polymer:

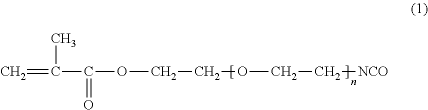

where “n” represents an integer of 1 or more.

### A-1. Base Polymer

The base polymer is a polymer obtained by polymerizing a monomer composition containing a polymer having a hydroxy group and a monomer represented by formula (1) (hereinafter also referred to as “monomer composition for a base polymer”). The polymerization of the monomer composition for a base polymer may cause the addition polymerization of the monomer represented by formula (1) to the polymer having a hydroxy group. As a result, a polymer having a structural unit derived from the monomer represented by formula (1) is obtained. The use of the polymer as the base polymer can provide a pressure-sensitive adhesive composition, which has an excellent unevenness-embedding property and an excellent pressure-sensitive adhesive property, and can prevent an adhesive residue on an adherend at the time of its peeling:

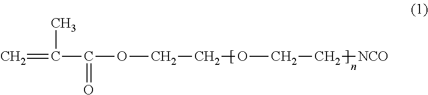

where “n” represents an integer of 1 or more.

The weight-average molecular weight of the base polymer is preferably 300,000 or more, more preferably 400,000 or more, still more preferably from 600,000 to 1,000,000. When the weight-average molecular weight falls within such ranges, there can be obtained a pressure-sensitive adhesive composition, which prevents the bleeding of a low-molecular weight component, and hence has a low contamination property. The molecular weight distribution (weight-average molecular weight/number-average molecular weight) of the base polymer is preferably from 1 to 20, more preferably from 3 to 10. The use of the base polymer having a narrow molecular weight distribution can provide a pressure-sensitive adhesive composition, which prevents the bleeding of a low-molecular weight component, and hence has a low contamination property. The weight-average molecular weight and the number-average molecular weight may be determined by gel permeation chromatography measurement (solvent: tetrahydrofuran, in terms of polystyrene).

A polymer obtained by introducing a hydroxy group into any appropriate polymer may be used as the polymer having a hydroxy group. Examples thereof include polymers each obtained by introducing a hydroxy group into a side chain and/or a terminal of a resin, such as a (meth)acrylic resin, a vinyl alkyl ether-based resin, a silicone-based resin, a polyester-based resin, a polyamide-based resin, a urethane-based resin, or a styrene-diene block copolymer. Of those, a polymer obtained by introducing a hydroxy group into the (meth)acrylic resin is preferably used. The use of the (meth)acrylic resin can provide a pressure-sensitive adhesive composition, which facilitates the adjustment of the storage modulus of elasticity and tensile modulus of elasticity of the pressure-sensitive adhesive layer, and is excellent in balance between its pressure-sensitive adhesive strength and peelability. Further, the contamination of an adherend by a component derived from the pressure-sensitive adhesive can be reduced. The term “(meth)acrylic” refers to acrylic and/or methacrylic.

The polymer having a hydroxy group is obtained by, for example, polymerizing a monomer composition containing an ester of acrylic acid or methacrylic acid having any appropriate linear or branched alkyl group, and a monomer having a hydroxy group. The esters of acrylic acid or methacrylic acid each having a linear or branched alkyl group may be used alone or in combination thereof.

The linear or branched alkyl group is preferably an alkyl group having 30 or less carbon atoms, more preferably an alkyl group having 1 to 20 carbon atoms, still more preferably an alkyl group having 4 to 18 carbon atoms. Specific examples of the alkyl group include a methyl group, an ethyl group, a propyl group, an isopropyl group, a n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group.

Any appropriate monomer may be used as the hydroxy group-containing monomer. Examples thereof include 2-hydroxymethyl acrylate, 2-hydroxyethyl acrylate, 2-hydroxypropyl acrylate, 3-hydroxypropyl acrylate, 4-hydroxybutyl acrylate, 2-hydroxymethyl methacrylate, 2-hydroxyethyl methacrylate, and N-(2-hydroxyethyl)acrylamide. Of those, 2-hydroxymethyl acrylate, 2-hydroxyethyl acrylate, 2-hydroxymethyl methacrylate, and 2-hydroxyethyl methacrylate are preferably used. Those monomers may be used alone or in combination thereof.

The ratio of the hydroxy group-containing monomer is preferably from 10 mol % to 40 mol %, more preferably from 10 mol % to 30 mol %, still more preferably from 15 mol % to 25 mol % with respect to 100 mol % of all the monomer components of the monomer composition to be used in the polymerization of the polymer having a hydroxy group. The polymerization of the monomer composition containing the hydroxy group-containing monomer provides the polymer having a hydroxy group. The hydroxy group may serve as the point into which the structural unit derived from the monomer represented by formula (1) is introduced. For example, a base polymer having a carbon unsaturated double bond is obtained by causing the polymer having a hydroxy group (prepolymer) and the monomer represented by formula (1) to react with each other.

Any other monomer component copolymerizable with the above-mentioned (meth)acrylic acid alkyl ester may be further used as required for the purpose of modifying, for example, the cohesive strength, heat resistance, and cross-linkability of the pressure-sensitive adhesive composition. Examples of such monomer component include carboxyl group-containing monomers, such as acrylic acid and methacrylic acid; acid anhydride monomers, such as maleic anhydride and itaconic anhydride; sulfonic acid group-containing monomers, such as styrenesulfonic acid and allylsulfonic acid; (N-substituted) amide-based monomers, such as (meth)acrylamide and N,N-dimethyl(meth)acrylamide; aminoalkyl (meth)acrylate-based monomers such as aminoethyl (meth)acrylate; alkoxyalkyl (meth)acrylate-based monomers such as methoxyethyl (meth)acrylate; maleimide-based monomers, such as N-cyclohexylmaleimide and N-isopropylmaleimide; itaconimide-based monomers, such as N-methylitaconimide and N-ethylitaconimide; succinimide-based monomers; vinyl-based monomers, such as vinyl acetate, vinyl propionate, N-vinylpyrrolidone, and methylvinylpyrrolidone; cyanoacrylate monomers, such as acrylonitrile and methacrylonitrile; epoxy group-containing acrylic monomers such as glycidyl (meth)acrylate; glycol-based acrylic ester monomers, such as polyethylene glycol (meth)acrylate and polypropylene glycol (meth)acrylate; acrylic acid ester-based monomers each having a heterocycle, a halogen atom, or a silicon atom, such as tetrahydrofurfuryl (meth)acrylate, fluorinated (meth)acrylate, and silicone (meth)acrylate; olefin-based monomers, such as isoprene, butadiene, and isobutylene; and vinyl ether-based monomers such as vinyl ether. Those monomer components may be used alone or in combination thereof.

The content ratio of the other monomer component copolymerizable with the (meth)acrylic acid alkyl ester in the monomer composition may be set to any appropriate amount. Specifically, the other monomer component copolymerizable with the (meth)acrylic acid alkyl ester is used so that the total amount of the (meth)acrylic acid alkyl ester, the hydroxy group-containing monomer, and any appropriate other monomer component copolymerizable with the (meth)acrylic acid alkyl ester may be 100 mol %.

The polymer having a hydroxy group may be obtained by any appropriate method. For example, the polymer may be obtained by polymerizing the monomer composition containing the (meth)acrylic acid alkyl ester, the hydroxy group-containing monomer, and any appropriate other monomer component copolymerizable with the (meth)acrylic acid alkyl ester by any appropriate polymerization method.

As described above, the base polymer of the pressure-sensitive adhesive composition is a polymer obtained by polymerizing the monomer composition containing the polymer having a hydroxy group and the monomer represented by formula (1). The reaction of the hydroxy group of the polymer having a hydroxy group and the isocyanate group of the monomer represented by formula (1) provides a base polymer having introduced thereinto a carbon unsaturated double bond. The use of the base polymer can provide a pressure-sensitive adhesive composition, which has an excellent unevenness-embedding property and an excellent pressure-sensitive adhesive property, and can prevent an adhesive residue on an adherend at the time of its peeling:

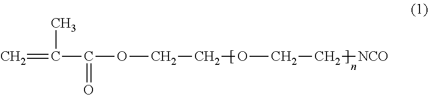

where “n” represents an integer of 1 or more.

In the formula (1) , “n” represents an integer of 1 or more, preferably from 1 to 10, more preferably from 1 to 5. When “n” falls within these ranges, a pressure-sensitive adhesive composition further suppressed from causing adhesive residue can be provided. In at least one embodiment of the present disclosure, the monomer represented by formula (1) is 2-(2-methacryloyloxyethyloxy) ethyl isocyanate (compound represented by the formula (1) in which “n” represents 1). The monomers each represented by formula (1) may be used alone or in combination thereof.

The addition amount of the monomer represented by formula (1) with respect to the number of moles of the hydroxy groups of the polymer having a hydroxy group is preferably from 50 mol % to 95 mol %, more preferably from 65 mol % to 90 mol %, still more preferably from 70 mol % to 85 mol %. When the addition amount of the monomer represented by formula (1) falls within the ranges, there can be provided a pressure-sensitive adhesive composition, which can be cured by UV irradiation and is excellent in peelability. When the addition amount of the monomer represented by formula (1) is more than 95 mol %, the number of points at which the base polymer reacts with the cross-linking agent may reduce to make it impossible to obtain a sufficient cross-linking effect.

The base polymer may have a portion into which a carbon unsaturated double bond is introduced by using a compound having a carbon unsaturated double bond except the monomer represented by formula (1). Examples of the compound having a carbon unsaturated double bond except the monomer represented by formula (1) include 2-isocyanatoethyl acrylate (2-acryloyloxyethyl isocyanate), 2-isocyanatoethyl methacrylate (2-methacryloyloxyethyl isocyanate), methacryloisocyanate, 1,1-(bisacryloyloxymethyl)ethyl isocyanate, and m-isopropenyl-α,α-dimethylbenzyl isocyanate. Those compounds may be used alone or in combination thereof. When the compound having a carbon unsaturated double bond except the monomer represented by formula (1) is used in combination, the monomer represented by formula (1) and the compound having a carbon unsaturated double bond except the monomer represented by formula (1) are used so that the total addition amount thereof may be 95 mol % or less.

### A-2. Photopolymerization Initiator

Any appropriate initiator may be used as the photopolymerization initiator. Examples of the photopolymerization initiator include acyl phosphine oxide-based photoinitiators, such as ethyl 2,4,6-trimethylbenzylphenyl phosphinate and (2,4,6-trimethylbenzoyl)-phenylphosphine oxide; α-ketol-based compounds, such as 4-(2-hydroxyethoxy)phenyl(2-hydroxy-2-propyl) ketone, α-hydroxy-α,α′-dimethylacetophenone, 2-methyl-2-hydroxypropiophenone, and 1-hydroxycyclohexyl phenyl ketone; acetophenone-based compounds, such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether-based compounds, such as benzoin ethyl ether, benzoin isopropyl ether, and anisoin methyl ether; ketal-based compounds such as benzyl dimethyl ketal; aromatic sulfonyl chloride-based compounds, such as 2-naphthalenesulfonyl chloride; photoactive oxime-based compounds, such as 1-phenone-1,1-propanedione-2-(o-ethoxycarbonyl) oxime; benzophenone-based compounds, such as benzophenone, benzoylbenzoic acid, and 3,3′-dimethyl-4-methoxybenzophenone; thioxanthone-based compounds, such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; and acyl phosphonates, and a-hydroxyacetophenones such as 2-hydroxy-1-(4-(4-(2-hydroxy-2-methylpropionyl)benzyl)phenyl-2-methylpropane-1. Of those, 2,2-dimethoxy-2-phenylacetophenone and 2-hydroxy-1-(4-(4-(2-hydroxy-2-methylpropionyl)benzyl)phenyl-2-methylpropane-1 may be preferably used. The photopolymerization initiators may be used alone or in combination thereof.

As the photopolymerization initiator, a commercially available product may also be used. Examples thereof include products available under the product names of Omnirad 127D and Omnirad 651 from IGM Resins B.V.

The photopolymerization initiator may be used in any appropriate amount. The content of the photopolymerization initiator is preferably from 0.5 part by weight to 20 parts by weight, more preferably from 0.5 part by weight to 10 parts by weight with respect to 100 parts by weight of the above-mentioned base polymer. When the content of the photopolymerization initiator is less than 0.5 part by weight, the pressure-sensitive adhesive may not be sufficiently cured at the time of active energy ray irradiation. When the content of the photopolymerization initiator is more than 20 parts by weight, the storage stability of the pressure-sensitive adhesive composition may reduce.

### A-3. Additive

The pressure-sensitive adhesive composition may further contain any appropriate additive. Examples of the additive include a cross-linking agent, a catalyst (e.g., a platinum catalyst), a tackifier, a plasticizer, a pigment, a dye, a filler, an age resistor, a conductive material, a UV absorber, a light stabilizer, a peeling modifier, a softener, a surfactant, a flame retardant, and a solvent.

In at least one embodiment of the present disclosure, the pressure-sensitive adhesive composition may further contain a cross-linking agent. Examples of the cross-linking agent include an isocyanate-based cross-linking agent, an epoxy-based cross-linking agent, an aziridine-based cross-linking agent, and a chelate-based cross-linking agent. The content ratio of the cross-linking agent may be adjusted to any appropriate ratio. For example, when the isocyanate-based cross-linking agent is used, the content ratio is preferably from 0.01 part by weight to 10 parts by weight, more preferably from 0.1 part by weight to 5 parts by weight, still more preferably from 3.0 parts by weight to 5.0 parts by weight with respect to 100 parts by weight of the base polymer. The flexibility of the pressure-sensitive adhesive layer formed from the pressure-sensitive adhesive composition can be controlled by the content ratio of the cross-linking agent. When the content of the cross-linking agent is less than 0.01 part by weight, the pressure-sensitive adhesive composition becomes sol, and hence the pressure-sensitive adhesive layer may not be formed. When the content of the cross-linking agent is more than 10 parts by weight, adhesiveness to an adherend may reduce, and the adherend may not be sufficiently protected.

In at least one embodiment of the present disclosure, the isocyanate-based cross-linking agent is preferably used. The isocyanate-based cross-linking agent is preferred because the cross-linking agent can react with many kinds of functional groups. A cross-linking agent having 3 or more isocyanate groups is particularly preferably used. When the isocyanate-based cross-linking agent is used as the cross-linking agent and the content ratio of the cross-linking agent falls within the above-mentioned ranges, a pressure-sensitive adhesive layer excellent in peelability even after heating and causing a remarkably reduced amount of an adhesive residue can be formed.

### B. Pressure-Sensitive Adhesive Tape for Semiconductor Processing

In at least one embodiment of the present disclosure, there is provided a pressure-sensitive adhesive tape for semiconductor processing. The pressure-sensitive adhesive tape for semiconductor processing includes a base material and a pressure-sensitive adhesive layer formed from the above-mentioned pressure-sensitive adhesive composition. As described above, the pressure-sensitive adhesive composition has an excellent unevenness-embedding property and an excellent pressure-sensitive adhesive property, and can prevent an adhesive residue on an adherend at the time of its peeling. Accordingly, when the pressure-sensitive adhesive layer is formed by using the pressure-sensitive adhesive composition, even in the case where a semiconductor wafer has unevenness on its surface, the tape has an excellent unevenness-embedding property and an excellent pressure-sensitive adhesive property at the time of its bonding to the semiconductor wafer, and can appropriately protect the surface of the semiconductor wafer in a semiconductor processing step. As described above, the pressure-sensitive adhesive composition includes the photopolymerization initiator. Accordingly, the tape can exhibit excellent peelability at the time of its peeling by being irradiated with UV light, and can prevent an adhesive residue on the surface of an adherend even when the adherend has unevenness such as a bump.

In at least one embodiment of the present disclosure, the pressure-sensitive adhesive tape preferably includes an intermediate layer between the base material and the pressure-sensitive adhesive layer. When the tape includes the intermediate layer, in the case where the surface of an adherend has unevenness, the unevenness-embedding property of the tape can be further improved. The figure is a schematic sectional view of the pressure-sensitive adhesive tape according to at least one embodiment of the present disclosure. A pressure-sensitive adhesive tape 100 of the illustrated example includes a base material 30, an intermediate layer 20, and a pressure-sensitive adhesive layer 10. The pressure-sensitive adhesive layer 10 is a layer formed from the above-mentioned pressure-sensitive adhesive composition.

The thickness of the pressure-sensitive adhesive tape may be set within any appropriate range. The thickness is preferably from 10 μm to 1,000 μm, more preferably from 50 μm to 300 μm, still more preferably from 100 μm to 300 μm.

### B-1. Base Material

The base material may be formed of any appropriate resin. Specific examples of the resin for forming the base material include polyester-based resins, such as polyethylene terephthalate (PET), polyethylene naphthalate (PEN), polybutylene terephthalate (PBT), and polybutylene naphthalate (PBN); polyolefin-based resins, such as an ethylene-vinyl acetate copolymer, an ethylene-methyl methacrylate copolymer, polyethylene, polypropylene, and an ethylene-propylene copolymer; polyvinyl alcohol; polyvinylidene chloride; polyvinyl chloride; a vinyl chloride-vinyl acetate copolymer; polyvinyl acetate; polyamide; polyimide; celluloses; fluorine-based resins; polyether; polystyrene-based resins such as polystyrene; polycarbonate; and polyethersulfone. Of those, polyethylene terephthalate, polyethylene naphthalate, polybutylene terephthalate, and polybutylene naphthalate are preferably used. The use of these resins can further prevent the occurrence of warpage.

The base material may further contain any other component to the extent that the effects of the present disclosure are not impaired. Examples of the other component include an antioxidant, a UV absorber, a light stabilizer, and a heat stabilizer. With regard to the kind and the usage amount of the other component, any appropriate kind of component may be used in any appropriate amount in accordance with purposes.

In at least one embodiment of the present disclosure, the base material has an antistatic function. When the base material has the antistatic function, the occurrence of static electricity at the time of the peeling of the tape is suppressed, and hence the breakage of a circuit and the adhesion of foreign matter due to the static electricity can be prevented. The base material may have the antistatic function by being formed from a resin containing an antistatic agent, or may have the antistatic function by applying a composition containing a conductive polymer, an organic or inorganic conductive substance, and an antistatic component such as the antistatic agent to any appropriate film to form an antistatic layer. When the base material has the antistatic layer, the intermediate layer is preferably laminated on its surface having formed thereon the antistatic layer.

When the base material has the antistatic function, the surface resistance value of the base material is, for example, from 1.0×10² Ω/□ to 1.0×10²³ Ω/□, preferably from 1.0×10⁶ Ω/□ to 1.0×10¹² Ω/□, more preferably from 1.0×10⁷ Ω/□ to 1.0×10²² Ω/□. When the surface resistance value falls within the ranges, the occurrence of static electricity at the time of the peeling of the tape is suppressed, and hence the breakage of a circuit and the adhesion of foreign matter due to the static electricity can be prevented. When the base material having the antistatic function is used as the base material, the surface resistance value of the pressure-sensitive adhesive tape to be obtained may be, for example, from 1.0×10⁶ Ω/□ to 1.0×10¹² Ω/□.

The thickness of the base material may be set to any appropriate value. The thickness of the base material is preferably from 10 μm to 200 μm, more preferably from 20 μm to 150 μm.

The modulus of elasticity of the base material may be set to any appropriate value. The modulus of elasticity of the base material at 25° C. is preferably from 50 MPa to 6,000 MPa, more preferably from 70 MPa to 5,000 MPa. When the modulus of elasticity falls within these ranges, a pressure-sensitive adhesive tape that can moderately follow the unevenness of the surface of an adherend can be obtained.

### B-2. Pressure-Sensitive Adhesive Layer

The pressure-sensitive adhesive layer may be formed from the pressure-sensitive adhesive composition described in the above-mentioned section A. As described above, the pressure-sensitive adhesive composition described in the section A has an excellent unevenness-embedding property and an excellent pressure-sensitive adhesive property, and can prevent an adhesive residue on an adherend at the time of its peeling. Accordingly, when the pressure-sensitive adhesive layer is formed by using the pressure-sensitive adhesive composition, even in the case where a semiconductor wafer has unevenness on its surface, the pressure-sensitive adhesive tape has an excellent unevenness-embedding property and an excellent pressure-sensitive adhesive property at the time of its bonding to the semiconductor wafer, and can appropriately protect the surface of the semiconductor wafer in a semiconductor processing step.

The thickness of the pressure-sensitive adhesive layer may be set to any appropriate value. The thickness of the pressure-sensitive adhesive layer is preferably from 1 μm to 10 μm, more preferably from 1 μm to 6 μm. When the thickness of the pressure-sensitive adhesive layer falls within these ranges, the tape can exhibit a sufficient pressure-sensitive adhesive strength to an adherend.

The pressure-sensitive adhesive layer has a shear storage modulus of elasticity G′1 at 25° C. of preferably 0.175 MPa or more, more preferably 0.2 MPa or more, still more preferably 0.23 MPa or more when not being irradiated with UV light. When the shear storage modulus of elasticity G′1 at 25° C. falls within the ranges, even in the case where an adherend has unevenness, the pressure-sensitive adhesive tape can exhibit an excellent unevenness-embedding property. The shear storage modulus of elasticity G′1of the pressure-sensitive adhesive layer at 25° C. is, for example, 0.80 MPa or less. The term “shear storage modulus of elasticity G′1 at 25° C.” as used herein refers to the value of a sample, which has formed thereon a pressure-sensitive adhesive layer having a thickness of 1 mm by using the pressure-sensitive adhesive composition, measured with a dynamic viscoelasticity-measuring apparatus.

The pressure-sensitive adhesive layer has a tensile storage modulus of elasticity E′1 at 25° C. of preferably 300 MPa or less, more preferably 200 MPa or less, still more preferably 180 MPa or less after its UV irradiation. When the tensile storage modulus of elasticity E′1 at 25° C. after the UV irradiation falls within the ranges, the pressure-sensitive adhesive tape can be easily peeled from an adherend after the UV irradiation. The tensile storage modulus of elasticity E′1 of the pressure-sensitive adhesive layer at 25° C. after the UV irradiation is 50 MPa or more. The term “tensile storage modulus of elasticity E′1 at 25° C. after the UV irradiation” as used herein refers to a value obtained as follows: a sample, which has formed thereon a pressure-sensitive adhesive layer having a thickness of 1 mm by using the pressure-sensitive adhesive composition, is produced; and the pressure-sensitive adhesive layer is irradiated with UV light so that an integrated light quantity may be 700 mJ/cm², followed by the measurement of the value with a dynamic viscoelasticity-measuring apparatus.

The pressure-sensitive adhesive layer has a pressure-sensitive adhesive strength to silicon of preferably 0.15 N/20 mm or less, more preferably 0.10 N/20 mm or less, still more preferably 0.08 N/20 mm or less after the UV irradiation. When the pressure-sensitive adhesive strength to silicon falls within the ranges, the pressure-sensitive adhesive tape can be easily peeled from an adherend after the UV irradiation. The pressure-sensitive adhesive strength to silicon after the UV irradiation is, for example, 0.01 N/20 mm or more. The term “pressure-sensitive adhesive strength to silicon” as used herein refers to a pressure-sensitive adhesive strength to a silicon mirror wafer measured with a pressure-sensitive adhesive tape having formed thereon a UV-curable pressure-sensitive adhesive layer.

The number of the pressure-sensitive adhesive layers may be one, or two or more. When the number of the pressure-sensitive adhesive layers is two or more, the pressure-sensitive adhesive tape only needs to include at least one pressure-sensitive adhesive layer formed by using the pressure-sensitive adhesive composition described in the above-mentioned section A. When the number of the pressure-sensitive adhesive layers is two or more, the pressure-sensitive adhesive layer formed by using the pressure-sensitive adhesive composition described in the section A is preferably formed on the surface of the pressure-sensitive adhesive tape to be brought into contact with an adherend. The pressure-sensitive adhesive layer that is not formed from the pressure-sensitive adhesive composition may be formed from any appropriate pressure-sensitive adhesive composition. The pressure-sensitive adhesive composition may be a UV-curable pressure-sensitive adhesive, or may be a pressure-sensing pressure-sensitive adhesive.

### B-3. Intermediate Layer

The intermediate layer may be formed of any appropriate material. The intermediate layer may be formed of, for example, a resin, such as an acrylic resin, a polyethylene-based resin, an ethylene-vinyl alcohol copolymer, an ethylene vinyl acetate-based resin, or an ethylene methyl methacrylate resin, or a pressure-sensitive adhesive.

In at least one embodiment of the present disclosure, the intermediate layer is formed of a composition for forming an intermediate layer containing a (meth)acrylic polymer. The (meth)acrylic polymer preferably contains a constituent component derived from an alkyl (meth)acrylate. Examples of the alkyl (meth)acrylate include (meth)acrylic acid C1-C20 alkyl esters, such as methyl (meth)acrylate, ethyl (meth)acrylate, propyl (meth)acrylate, isopropyl (meth)acrylate, n-butyl (meth)acrylate, isobutyl (meth)acrylate, s-butyl (meth)acrylate, pentyl (meth)acrylate, isopentyl (meth)acrylate, hexyl (meth)acrylate, heptyl (meth) acrylate, 2-ethylhexyl (meth) acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth) acrylate, hexadecyl (meth) acrylate, heptadecyl (meth) acrylate, octadecyl (meth) acrylate, nonadecyl (meth)acrylate, and eicosyl (meth)acrylate.

The (meth)acrylic polymer may contain a constituent unit corresponding to another monomer copolymerizable with the alkyl (meth)acrylate as required for the purpose of modifying, for example, cohesive strength, heat resistance, or cross-linkability. Examples of such monomer include carboxyl group-containing monomers, such as acrylic acid and methacrylic acid; acid anhydride monomers, such as maleic anhydride and itaconic anhydride; hydroxyl group-containing monomers, such as hydroxyethyl (meth)acrylate and hydroxypropyl (meth)acrylate; sulfonic acid group-containing monomers, such as styrenesulfonic acid and allylsulfonic acid; nitrogen-containing monomers, such as (meth)acrylamide, N,N-dimethyl (meth)acrylamide, and acryloyl morpholine; aminoalkyl (meth)acrylate-based monomers such as aminoethyl (meth) acrylate; alkoxyalkyl (meth)acrylate-based monomers such as methoxyethyl (meth)acrylate; maleimide-based monomers, such as N-cyclohexyl maleimide and N-isopropyl maleimide; itaconimide-based monomers, such as N-methyl itaconimide and N-ethyl itaconimide; succinimide-based monomers; vinyl-based monomers, such as vinyl acetate, vinyl propionate, N-vinyl pyrrolidone, and methylvinyl pyrrolidone; cyano acrylate monomers, such as acrylonitrile and methacrylonitrile; epoxy group-containing acrylic monomers such as glycidyl (meth)acrylate; glycol-based acrylic ester monomers, such as polyethylene glycol (meth)acrylate and polypropylene glycol (meth)acrylate; acrylic acid ester-based monomers each having a heterocycle, a halogen atom, or a silicon atom, such as tetrahydrofurfuryl (meth)acrylate, fluorinated (meth)acrylate, and silicone (meth)acrylate; olefin-based monomers, such as isoprene, butadiene, and isobutylene; and vinyl ether-based monomers such as vinyl ether. Those monomer components may be used alone or in combination thereof. The content ratio of the constituent unit derived from the other monomer is preferably from 1 part by weight to 30 parts by weight, more preferably from 3 parts by weight to 25 parts by weight in 100 parts by weight of the acrylic polymer.

The (meth)acrylic polymer has a weight-average molecular weight of preferably from 200,000 to 1,000,000, more preferably from 300,000 to 800,000. The weight-average molecular weight may be measured by GPC (solvent: THF).

The (meth)acrylic polymer has a glass transition temperature of preferably from −50° C. to 30° C., more preferably from −40° C. to 20° C. When the glass transition temperature falls within such ranges, a pressure-sensitive adhesive tape that is excellent in heat resistance and that can be suitably used in a heating step can be obtained.

In at least one embodiment of the present disclosure, the intermediate layer contains a photopolymerization initiator and is free of any UV-curable component. That is, although the intermediate layer contains the photopolymerization initiator, the intermediate layer itself is not cured by UV irradiation. Accordingly, the intermediate layer can maintain its flexibility before and after UV irradiation. In addition, when the intermediate layer contains the photopolymerization initiator, the migration of the photopolymerization initiator in the pressure-sensitive adhesive layer to the intermediate layer, which results in a reduction in content of the photopolymerization initiator in the pressure-sensitive adhesive layer over time, can be suppressed. Accordingly, after UV irradiation, the pressure-sensitive adhesive tape can exhibit excellent light peelability. The term “UV-curable component” as used herein refers to a component capable of cross-linking through UV irradiation to undergo curing shrinkage. Specific examples thereof include the polymers each having a carbon unsaturated double bond in a side chain thereof or a terminal thereof.

The photopolymerization initiator in the composition for forming an intermediate layer (the resulting intermediate layer) and the photopolymerization initiator in the pressure-sensitive adhesive layer may be identical to or different from each other. The intermediate layer and the pressure-sensitive adhesive layer preferably contain the same photopolymerization initiator. When the intermediate layer and the pressure-sensitive adhesive layer contain the same photopolymerization initiator, the transfer of the photopolymerization initiator from the pressure-sensitive adhesive layer to the intermediate layer can be further suppressed. The photopolymerization initiator taken as an example in the above-mentioned section A may be used as the photopolymerization initiator. The photopolymerization initiators may be used alone or in combination thereof.

The content of the photopolymerization initiator in the intermediate layer is preferably from 0.1 part by weight to 10 parts by weight, more preferably from 0.5 part by weight to 8 parts by weight with respect to 100 parts by weight of a polymer constituent component in the composition for forming an intermediate layer. When the content of the photopolymerization initiator in the intermediate layer falls within the ranges, a pressure-sensitive adhesive tape having excellent light peelability after UV irradiation can be obtained. In at least one embodiment of the present disclosure, the photopolymerization initiator is used in an equal amount to that in the composition for forming a pressure-sensitive adhesive layer.

In at least one embodiment of the present disclosure, the composition for forming an intermediate layer further contains a cross-linking agent. Examples of the cross-linking agent include an isocyanate-based cross-linking agent, an epoxy-based cross-linking agent, an oxazoline-based cross-linking agent, an aziridine-based cross-linking agent, a melamine-based cross-linking agent, a peroxide-based cross-linking agent, a urea-based cross-linking agent, a metal alkoxide-based cross-linking agent, a metal chelate-based cross-linking agent, a metal salt-based cross-linking agent, a carbodiimide-based cross-linking agent, and an amine-based cross-linking agent.

When the composition for forming an intermediate layer contains the cross-linking agent, the content ratio of the cross-linking agent is preferably from 0.01 part by weight to 5 parts by weight, more preferably from 0.05 part by weight to 1.0 part by weight with respect to 100 parts by weight of the polymer constituent component in the composition for forming an intermediate layer.

The composition for forming an intermediate layer may further contain any appropriate additive as required. Examples of the additive include an active energy ray polymerization accelerator, a radical scavenger, a tackifier, a plasticizer (e.g., a trimellitic acid ester-based plasticizer or a pyromellitic acid ester-based plasticizer), a pigment, a dye, a filler, an age resistor, a conductive material, an antistatic agent, a UV absorber, a light stabilizer, a peeling modifier, a softener, a surfactant, a flame retardant, and an antioxidant.

The thickness of the intermediate layer is preferably from 10 μm to 300 μm, more preferably from 50 μm to 200 μm, still more preferably from 50 μm to 150 μm, particularly preferably from 100 μm to 150 μm. When the thickness of the intermediate layer falls within these ranges, a pressure-sensitive adhesive tape that can satisfactorily embed an uneven surface can be obtained.

The intermediate layer has a shear storage modulus of elasticity G′3 at 25° C. of preferably from 0.3 MPa to 10 MPa, more preferably from 0.4 MPa to 1.5 MPa, still more preferably from 0.5 MPa to 1.0 MPa before its UV irradiation. In addition, the intermediate layer has a shear storage modulus of elasticity G′4 at 80° C. of preferably from 0.01 MPa to 0.5 MPa, more preferably from 0.02 MPa to 0.20 MPa, still more preferably from 0.02 MPa to 0.15 MPa, particularly preferably from 0.03 MPa to 0.10 MPa before the UV irradiation. When the shear storage modulus of elasticity G′3 at 25° C. and the shear storage modulus of elasticity G′4 at 80° C. fall within the ranges, a pressure-sensitive adhesive tape that can satisfactorily embed an uneven surface at the time of its bonding and in a backgrinding step can be obtained. In addition, the adherend-holding strength of the pressure-sensitive adhesive tape can be improved.

### C. Method of Producing Pressure-Sensitive Adhesive Tape

The pressure-sensitive adhesive tape may be produced by any appropriate method. In at least one embodiment of the present disclosure, the pressure-sensitive adhesive tape may be produced by forming the pressure-sensitive adhesive layer on the base material. In addition, when the pressure-sensitive adhesive tape includes the intermediate layer, the pressure-sensitive adhesive tape may be produced by, for example, forming the intermediate layer on the base material, and then forming the pressure-sensitive adhesive layer on the intermediate layer. The pressure-sensitive adhesive layer and the intermediate layer may be formed by applying the composition for forming a pressure-sensitive adhesive layer and the composition for forming an intermediate layer onto the base material and the intermediate layer, respectively, or may each be formed by forming the layer on any appropriate release liner and then transferring the layer. Various methods, such as bar coater coating, air knife coating, gravure coating, gravure reverse coating, reverse roll coating, lip coating, die coating, dip coating, offset printing, flexographic printing, and screen printing, may each be adopted as a method for the application. In addition, for example, a method involving separately forming the pressure-sensitive adhesive layer or the intermediate layer on a release liner and then bonding the resultant to the base material may be adopted.

### D. Applications of Pressure-Sensitive Adhesive Tape for Semiconductor Processing

The pressure-sensitive adhesive tape for semiconductor processing according to at least one embodiment of the present disclosure may be used in any appropriate step of a semiconductor processing step. As described above, the pressure-sensitive adhesive tape for semiconductor processing according to at least one embodiment of the present disclosure has an excellent unevenness-embedding property and an excellent pressure-sensitive adhesive property, and can prevent an adhesive residue on an adherend at the time of its peeling. Accordingly, when the pressure-sensitive adhesive layer is formed by using the pressure-sensitive adhesive composition, even in the case where a semiconductor wafer has unevenness on its surface, the tape has an excellent unevenness-embedding property and an excellent pressure-sensitive adhesive property at the time of its bonding to the semiconductor wafer, and can appropriately protect the surface of the semiconductor wafer in a semiconductor processing step. As described above, the pressure-sensitive adhesive composition includes the photopolymerization initiator. Accordingly, the tape can exhibit excellent peelability at the time of its peeling by being irradiated with UV light, and can prevent adhesive residue on the surface of an adherend even when the adherend has unevenness such as a bump. Accordingly, the tape may be suitably used in an application where excellent pressure-sensitive adhesive strength and excellent peel strength are required. In at least one embodiment of the present disclosure, the pressure-sensitive adhesive tape for semiconductor processing according to at least one embodiment of the present disclosure may be used by being bonded to an adherend having unevenness on its surface. In such adherend, the property by which the unevenness of the surface of the adherend is embedded and a preventing effect on adhesive residue at the time of the peeling of the tape may be further required. Even when such adherend is used, the pressure-sensitive adhesive tape for semiconductor processing according to at least one embodiment of the present disclosure can satisfactorily hold the adherend in the semiconductor processing step.

In at least one embodiment of the present disclosure, the above-mentioned pressure-sensitive adhesive tape may be suitably used as a backgrinding tape. The pressure-sensitive adhesive tape can exhibit excellent light peelability after its UV irradiation. In addition, after the UV irradiation, the tape can exhibit excellent light peelability irrespective of the structure of the surface of an adherend. Accordingly, even when the structure of the surface of the adherend is complicated, the tape can prevent an adhesive residue on the surface of the adherend. Accordingly, the tape can be easily peeled from the adherend after a backgrinding step, and can prevent an adhesive residue on the adherend.

### EXAMPLES

Now, the present disclosure is specifically described by way of examples, but the present disclosure is not limited to these examples. Test and evaluation methods in the examples are as described below. In addition, “part(s)” and “%” are by weight unless otherwise stated.

### <Production Example 1> Preparation of Intermediate Layer-Forming Composition

58.4 moles of butyl acrylate, 38.6 mol of methyl methacrylate, and 3 mol of 2-hydroxyethyl acrylate (manufactured by Toagosei Co., Ltd., product name: ACRYCS (trademark) HEA) were used as monomers. Those monomers, 0.3 wt % of a polymerization initiator (manufactured by FUJIFILM Wako Pure Chemical Corporation, product name: V-50) with respect to the total weight of the monomers, and a solvent (water) were mixed to prepare a monomer composition (solid content concentration: 25%). The monomer composition was loaded into an experimental apparatus for polymerization obtained by mounting a 1-liter round-bottom separable flask with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 1 hour. After that, while the composition was stirred in a stream of nitrogen, the composition was held under 56° C. for 5 hours to be subjected to emulsion polymerization, followed by salting out. Thus, a resin (polymer for an intermediate layer-forming composition) was obtained.

The resultant polymer was dissolved in ethyl acetate, and 0.1 part by weight of a polyisocyanate compound (product name: “CORONATE L”, manufactured by Tosoh Corporation) and 1 part by weight of a photopolymerization initiator (manufactured by IGM Resins B.V., product name: Omnirad 127D) with respect to 100 parts by weight of the solid content of the solution were mixed into the solution. Thus, an intermediate layer-forming composition containing ethyl acetate (solid content: 35%) was prepared.

### <Production Example 2> Preparation of Pressure Sensitive Adhesive Layer-Forming Composition

75 moles of butyl acrylate, 25 mol of methyl methacrylate, and 20 mol of 2-hydroxyethyl acrylate (manufactured by Toagosei Co., Ltd., product name: ACRYCS (trademark) HEA) were used as monomers. Those monomers, 0.3 wt % of a polymerization initiator (manufactured by Tokyo Chemical Industry Co., Ltd., product name: 2,2′-azobis(isobutyronitrile) (AIBN)) with respect to the total weight of the monomers, and a solvent (ethyl acetate) were mixed to prepare a monomer composition (solid content concentration: 37.5%). The monomer composition was loaded into an experimental apparatus for polymerization obtained by mounting a 1-liter round-bottom separable flask with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 6 hours. After that, while the composition was stirred in a stream of nitrogen, the composition was held under 65° C. for 6 hours to be subjected to solution polymerization. Thus, a resin solution (polymer solution containing a polymer having a hydroxy group) was obtained.

The solution of the polymer having a hydroxy group obtained in the foregoing was stirred so that air sufficiently entered the solution. After that, 16 mol of a monomer represented by formula (1) (manufactured by Showa Denko K.K., product name: “Karenz MOI-EG”) was added to the solution. Further, 0.05 wt % of dibutyltin(IV) dilaurate (manufactured by Wako Pure Chemical Industries, Ltd.) with respect to the weight of the monomer represented by formula (1) was added to the mixture, and a solvent (ethyl acetate) was appropriately added to adjust the solid content concentration of the mixture to 31%, followed by stirring. After that, the mixture was stored at 50° C. for 24 hours to provide a polymer solution (pressure-sensitive adhesive composition 1).

3.0 parts by weight of a polyisocyanate compound (product name: “CORONATE L”, manufactured by Tosoh Corporation) and 1 part by weight of a photopolymerization initiator (manufactured by IGM Resins B.V., product name: Omnirad 127D) with respect to 100 parts by weight of the solid content of the resultant polymer solution were mixed into the solution. Thus, a pressure-sensitive adhesive layer-forming composition containing ethyl acetate (solid content: 15%) was prepared.

### Example 1

The intermediate layer-forming composition obtained in Production Example 1 was applied to the surface of a polyester-based release liner having a thickness of 38 μm (product name: “MRF”, manufactured by Mitsubishi Plastics, Inc.), the surface having been subjected to silicone treatment, and was heated at 120° C. for 120 seconds so that its solvent was removed. Thus, an intermediate layer having a thickness of 150 μm was formed. Next, the ESAS-treated surface of a PET film having a thickness of 50 μm (product name: “LUMIRROR S105”, manufactured by Toray Industries, Inc.), the film serving as a base material, was bonded to the surface of the intermediate layer.

Separately, the pressure-sensitive adhesive layer-forming composition obtained in Production Example 2 was applied to the silicone-treated surface of a polyester-based release liner having a thickness of 75 μm, and was heated at 120° C. for 120 seconds so that its solvent was removed. Thus, a pressure-sensitive adhesive layer having a thickness of 6 μm was formed.

Next, the release liner was peeled from the intermediate layer, and the pressure-sensitive adhesive layer was bonded and transferred onto the intermediate layer, followed by the storage of the resultant at 50° C. for 72 hours. Thus, a pressure-sensitive adhesive tape including the base material, the intermediate layer, and the pressure-sensitive adhesive layer in the stated order was obtained.

### Example 2

A pressure-sensitive adhesive tape was obtained in the same manner as in Example 1 except that the added amount of the monomer represented by formula (1) (manufactured by Showa Denko K.K., product name: “Karenz MOI-EG”) was changed to 14 mol.

### Example 3

A pressure-sensitive adhesive tape was obtained in the same manner as in Example 1 except that the added amount of the monomer represented by formula (1) (manufactured by Showa Denko K.K., product name: “Karenz MOI-EG”) was changed to 18 mol and the content of the photopolymerization initiator was changed to 2 parts by weight.

### Comparative Example 1

A pressure-sensitive adhesive tape was obtained in the same manner as in Example 3 except that another compound for introducing a carbon unsaturated double bond (manufactured by Showa Denko K.K., product name: “Karenz MOI”) was used instead of the monomer represented by formula (1) (manufactured by Showa Denko K.K., product name: “Karenz MOI-EG”) and the content of the photopolymerization initiator was changed to 1 part by weight. (Comparative Example 2)

75 moles of 2-ethylhexyl acrylate, 25 mol of acryloylmorpholine, 22 mol of 2-hydroxylethyl acrylate (manufactured by Toagosei Co., Ltd., product name: ACRYCS (trademark) HEA), 0.3 wt % of a polymerization initiator (manufactured by NOF Corporation, product name: NYPER (trademark) BW) with respect to the total weight of the monomers, and a solvent (ethyl acetate) were mixed to prepare a monomer composition (solid content concentration: 40%). The monomer composition was loaded into an experimental apparatus for polymerization obtained by mounting a 1-liter round-bottom separable flask with a separable cover, a separating funnel, a temperature gauge, a nitrogen-introducing tube, a Liebig condenser, a vacuum seal, a stirring rod, and a stirring blade. While the composition was stirred, the apparatus was purged with nitrogen at normal temperature for 6 hours. After that, while the composition was stirred in a stream of nitrogen, the composition was held under 60° C. for 8 hours to be subjected to polymerization. Thus, a resin solution was obtained. 11 moles of another compound for introducing a carbon unsaturated double bond (manufactured by Showa Denko K.K., product name: “Karenz MOI”) was added to the resultant resin solution. Further, 0.0633 part by weight of dibutyltin(IV) dilaurate (manufactured by Wako Pure Chemical Industries, Ltd.) was added to the mixture, and a solvent (toluene) was appropriately added to adjust the solid content concentration of the mixture to 15%. After that, under an air atmosphere, the mixture was stirred at 50° C. for 24 hours to provide a polymer solution (pressure-sensitive adhesive composition).

A pressure sensitive adhesive layer-forming composition was obtained in the same manner as in Example 1 except that the resultant pressure-sensitive adhesive composition was used and the content of the photopolymerization initiator was changed to 5 parts by weight. A pressure-sensitive adhesive tape was obtained in the same manner as in Example 1 except that the resultant pressure-sensitive layer-forming adhesive composition was used as a pressure-sensitive adhesive layer-forming composition.

### Comparative Example 3

A polymer solution (pressure-sensitive adhesive composition) was obtained in the same manner as in Comparative Example 2 except that 18 mol of the other compound for introducing a carbon unsaturated double bond (manufactured by Showa Denko K.K., product name: “Karenz MOI”) was used.

A pressure sensitive adhesive layer-forming composition was obtained in the same manner as in Example 1 except that the resultant pressure-sensitive adhesive composition was used and the content of the photopolymerization initiator was changed to 5 parts by weight. A pressure-sensitive adhesive tape was obtained in the same manner as in Example 1 except that the resultant pressure- sensitive adhesive layer-forming composition was used as a pressure-sensitive adhesive layer-forming composition.

The following evaluations were performed using the pressure-sensitive adhesive tapes obtained in the examples and comparative examples. The results are shown in Table 1.

### (1) Pressure-Sensitive Adhesive Strength

The silicon pressure-sensitive adhesive strength (Si pressure-sensitive adhesive strength) was measured by using a Si mirror wafer (manufactured by Shin-Etsu Chemical Co., Ltd.) as an adherend. The pressure-sensitive adhesive tape cut in 20 mm width with a cutter was used. The tape was bonded to the wafer by reciprocating a 2-kilogram roller once. The measurement was performed with a tensile testing machine (TENSILON) (manufactured by MinebeaMitsumi Inc., product name: TG-1kN) in conformity with JIS Z 0237 (2000). Specifically, the tape was peeled at a tensile rate of 300 ram/min, room temperature, and a peel angle of 180°. UV irradiation was performed as follows: the pressure-sensitive adhesive tape was bonded to the wafer, and the resultant was stored at normal temperature for 30 minutes, followed by the irradiation of the resultant with UV light (700 mJ/cm²) from a high-pressure mercury lamp before the measurement of the pressure-sensitive adhesive strength of the tape. The bonding and peeling of the pressure-sensitive adhesive tape were performed in an environment having a room temperature of 23° C. and a relative humidity of 50%.

### (2) Shear Storage Modulus of Elasticity

Each of the pressure-sensitive adhesive layer-forming compositions was laminated on a release liner (thickness: 38 μm, manufactured by Mitsubishi Plastics, Inc., product name: “MRF”) so as to have a thickness of 1 mm. Thus, a sample was obtained. The shear storage modulus of elasticity of the sample was measured with an ARES rheometer (manufactured by Waters Corporation) under the conditions of a rate of temperature increase of 5° C./min, a frequency of 1 Hz, and a measurement temperature of 0° C. to 100° C.

### (3) Tensile Storage Modulus of Elasticity

A sample was produced in the same manner as in the evaluation of the shear storage modulus of elasticity described above. The tensile storage modulus of elasticity of the sample was measured with a dynamic viscoelasticity-measuring apparatus (product name: RSA, manufactured by TA Instruments, Inc.) under the conditions of a rate of temperature increase of 5° C./min, a frequency of 1 Hz, and a measurement temperature of 0° C. to 100° C. The sample irradiated with UV light (700 mJ/cm²) from a high-pressure mercury lamp after the lamination of the pressure-sensitive adhesive layer-forming composition was subjected to the measurement.

### (4) Embedding Property

Each of the pressure-sensitive adhesive tapes (230 cm×400 cm) obtained in Examples and Comparative Examples was bonded to a wafer (8 inch, bump height: 75 μm, diameter: 90 μm, pitch: 200 μm) with a tape-bonding apparatus (manufactured by Nitto Seiki Co., Ltd., product name: DR-3000III). The bonding was performed under the following conditions.
Environment for performance: 23° C. and a relative humidity of 50%
Roller pressure: 0.40 MPa
Roller speed: 5 mm/sec
Table temperature: 80° C.

After the bonding, the bonding state of the pressure-sensitive adhesive tape and the wafer was observed with a laser microscope (magnification: 100 times). In addition, the pressure-sensitive adhesive tape and the wafer were imaged from the pressure-sensitive adhesive tape side under a state in which the pressure-sensitive adhesive tape faced upward, and the image was binarized (8-bit grayscale, brightness: 0 to 255, threshold: 114) with image analysis software (Image J (free software)). Five bumps were randomly selected, and the number of dots used for the display of one bump was counted. Evaluation was performed by marking a case in which the average number of dots for the five bumps was 830 or less with a circle symbol (good), and marking a case in which the average number of dots was more than 830 with an “x” symbol (bad). Note an image of only a bump in a state of having no tape bonded thereto has 220 dots. When a bump was in a state of having a tape bonded thereto, the number of dots is larger than 220. When the average number of dots of 830 or less indicates that the tape has an excellent unevenness-embedding property.

### (5) Adhesive Residue

Each of the pressure-sensitive adhesive tapes (230 cm×400 cm) obtained in Examples and Comparative Examples was bonded to a wafer having Cu pillars and bumps each including solder (12 inches, bump height: 65 μm, diameter: 60 μm, pitch: 150 μm) with a tape-bonding apparatus (manufactured by Nitto Seiki Co., Ltd., product name: DR-3000III). The bonding was performed under the following conditions.
Environment for performance: 23° C. and a relative humidity of 50%
Roller pressure: 0.40 MPa
Roller speed: 5 mm/sec
Table temperature: 80° C.

Next, the resultant was irradiated with UV light (700 mJ/cm²) from a high-pressure mercury lamp, and the pressure-sensitive adhesive tape was peeled with a peeling apparatus (manufactured by Nitto Seiki Co., Ltd., product name: RM300-NV4) under the following conditions.
Peeling temperature: 60° C.
Peel rate: 5 mm/sec

After that, the wafer after the peeling of the pressure-sensitive adhesive tape was observed with a laser microscope, and evaluation was performed by marking a case in which no adhesive residue was present on the bumps with a bullseye symbol (very good), marking a case in which adhesive residue was able to be slightly observed, but fell within an allowable range with a circle symbol(good), and marking a case in which adhesive residue was present on the bumps to preclude the use of the wafer with an “x” symbol(bad).

TABLE 1

| | | | | Example 1 | Example 2 | Example 3 |
|---|---|---|---|---|---|---|
| Configuration | Base | Thickness | | 50 | 50 | 50 |
| | material | [μm] | | | | |
| | | Composition | | PET | PET | PET |
| | Intermediate | Thickness | | 150 | 150 | 150 |
| | layer | [μm] | | | | |
| | | Polymer | | BA:MMA:HEA = | BA:MMA:HEA = | BA:MMA:HEA = |
| | | | | 58.4:38.6:3 (molar ratio) | 58.4:38.6:3 (molar ratio) | 58.4:38.6:3 (molar ratio) |
| | | Formulation | | Polymer:CORONATE | Polymer:CORONATE | Polymer:CORONATE |
| | | | | L:Omnirad | L:Omnirad | L:Omnirad |
| | | | | 127D = 100:0.1:1 | 127D = 100:0.1:1 | 127D = 100:0.1:1 |
| | Pressure- | Thickness | | 6 | 6 | 6 |
| | sensitive | [pm] | | | | |
| | adhesive | Polymer | | BA:MMA:HEA:MOI- | BA:MMA:HEA:MOI- | BA:MMA:HEA:MOI- |
| | layer | | | EG = 75:25:20:16 | EG = 75:25:20:14 | EG = 75:25:20:18 |
| | | | | (molar ratio) | (molar ratio) | (molar ratio) |
| | | Formulation | | Polymer:CORONATE | Polymer:CORONATE | Polymer:CORONATE |
| | | | | L:Omnirad | L:Omnirad | L:Omnirad |
| | | | | 127D = 100:3:l | 127D = 100:3:1 | 127D = 100:2:1 |
| Modulus of | Pressure- | 0 mJ | 25° C. | 0.249 | 0.291 | 0.177 |
| elasticity | sensitive | | 80° C. | 0.245 | 0.308 | 0.162 |
| | adhesive | 700 mJ | 25° C. | 272.8 | 169.9 | 152.7 |
| | layer | | 60° C. | 25.7 | 21.4 | 14.6 |
| | Intermediate | 0 mJ | 25° C. | 0.615 | 0.615 | 0.615 |
| | layer | | 80° C. | 0.069 | 0.069 | 0.069 |
| Silicon | Tape | 700 mJ | | 0.10 | 0.12 | 0.085 |
| pressure- | | | | | | |
| sensitive | | | | | | |
| adhesive | | | | | | |
| strength | | | | | | |
| Adhesive residue property | | | | ⊚ | ⊚ | ◯ |
| Embedding property | | | | ◯ | ◯ | ◯ |
| | | | | Comparative | Comparative | Comparative |
| | | | | Example 1 | Example 2 | Example 3 |
| Configuration | Base | Thickness | | 50 | 50 | 50 |
| | material | [μm] | | | | |
| | | Composition | | PET | PET | PET |
| | Intermediate | Thickness | | 150 | 150 | 150 |
| | layer | [μm] | | | | |
| | | Polymer | | BA:MMA:HEA = | BA:MMA:HEA = | BA:MMA:HEA = |
| | | | | 58.4:38.6:3 (molar ratio) | 58.4:38.6:3 (molar ratio) | 58.4:38.6:3 (molar ratio) |
| | | Formulation | | Polymer:CORONATE | Polymer:CORONATE | Polymer:CORONATE |
| | | | | L:Omnirad | L:Omnirad | L:Omnirad |
| | | | | 127D = 100:0.1:1 | 127D = 100:0.1:1 | 127D = 100:0.1:1 |
| | Pressure- | Thickness | | 6 | 6 | 6 |
| | sensitive | [pm] | | | | |
| | adhesive | Polymer | | BA:MMA:HEA:MOI = | EA: ACMO:HEA:MOI = | EA: ACMO:HEA:MOI = |
| | layer | | | 75:25:20:18 (molar | 75:25:22:11 | 75:25:22:18 |
| | | | | ratio) | | |
| | | Formulation | | Polymer:CORONATE | Polymer:CORONATE | Polymer:CORONATE |
| | | | | L:Omnirad | L:Omnirad | L:Omnirad |
| | | | | 127D = 100:1:1 | 127D = 100:5:1 | 127D = 100:5:l |
| Modulus of | Pressure- | 0 mJ | 25° C. | 0.172 | 0.52 | 0.51 |
| elasticity | sensitive | | 80° C. | 0.10 | 0.35 | 0.28 |
| | adhesive | 700 mJ | 25° C. | 564.10 | 97.69 | 297.40 |
| | layer | | 60° C. | 49.10 | 12.10 | 39.04 |
| | Intermediate | 0 mJ | 25° C. | 0.615 | 0.615 | 0.615 |
| | layer | | 80° C. | 0.069 | 0.069 | 0.069 |

| | | | | | |
|---|---|---|---|---|---|
| Silicon | Tape | 700 mJ | 0.090 | 0.20 | 0.08 |
| pressure- | | | | | |
| sensitive | | | | | |
| adhesive | | | | | |
| strength | | | | | |

| | | | |
|---|---|---|---|
| Adhesive residue property | X | ⊚ | X |
| Embedding property | ◯ | X | ◯ |

The pressure-sensitive adhesive composition according to at least one embodiment of the present disclosure can be suitably used in a pressure-sensitive adhesive tape for semiconductor processing.

According to at least one embodiment of the present disclosure, the pressure-sensitive adhesive composition, which has an excellent unevenness-embedding property and an excellent pressure-sensitive adhesive property, and can prevent an adhesive residue on an adherend at the time of its peeling, can be provided. Accordingly, the composition may be suitably used in a semiconductor processing step including using a semiconductor wafer having unevenness on its surface.

What is claimed is:

1. A pressure-sensitive adhesive composition to be used in a pressure-sensitive adhesive tape for semiconductor processing, comprising:
a base polymer; and
a photopolymerization initiator,
wherein the base polymer is obtained by polymerizing a monomer composition containing a polymer having a hydroxy group and a monomer represented by the following formula: 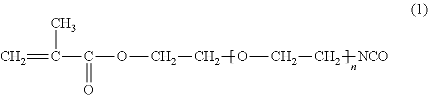
where “n” represents an integer of 1 or more.

2. The pressure-sensitive adhesive composition according to claim 1, wherein an addition amount of the monomer represented by the formula with respect to the number of moles of the hydroxy group of the polymer having a hydroxy group is from 50 mol % to 95 mol %.

3. The pressure-sensitive adhesive composition according to claim 1, wherein the monomer represented by the formula is 2-(2-methacryloyloxyethyloxy) ethyl isocyanate.

4. The pressure-sensitive adhesive composition according to claim 1, wherein a monomer composition to be used in polymerization of the polymer having a hydroxy group contains a hydroxy group-containing monomer at a ratio of 10 mol % to 40 mol %.

5. A pressure-sensitive adhesive tape for semiconductor processing, comprising:
a base material; and
a pressure-sensitive adhesive layer formed from the pressure-sensitive adhesive composition of claim 1.

6. The pressure-sensitive adhesive tape for semiconductor processing according to claim 5, wherein the pressure-sensitive adhesive tape for semiconductor processing is configured to be used in a backgrinding step.

7. The pressure-sensitive adhesive tape for semiconductor processing according to claim 5, wherein the pressure-sensitive adhesive layer has a shear storage modulus of elasticity at 25° C. of 0.2 MPa or more when free from being irradiated with UV light.

8. The pressure-sensitive adhesive tape for semiconductor processing according to claim 5, wherein the pressure-sensitive adhesive tape for semiconductor processing is configured to be bonded to an adherend having unevenness.

9. The pressure-sensitive adhesive tape for semiconductor processing according to claims 5, wherein the pressure-sensitive adhesive layer has a tensile storage modulus of elasticity at 25° C. of 200 MPa or less after UV irradiation.

10. The pressure-sensitive adhesive tape for semiconductor processing according to claims 5, wherein the pressure-sensitive adhesive layer has a pressure-sensitive adhesive strength to silicon of 0.15 N/20 mm or less after UV irradiation.
